(19) United States
(12) Patent Application Publication
(10) Pub. No.: US 2025/0185355 A1
(43) Pub. Date: Jun. 5, 2025

(54) STACKED NANOSHEET DEVICES WITH INTERFACIAL LAYERS

(71) Applicant: International Business Machines Corporation, Armonk, NY (US)

(72) Inventors: Debarghya Sarkar, Latham, NY (US); Takashi Ando, Eastchester, NY (US); Abir Shadman, Albany, NY (US); Shay Reboh, Guilderland, NY (US); Junli Wang, Slingerlands, NY (US); Paul Charles Jamison, Averill Park, NY (US)

(21) Appl. No.: 18/527,799

(22) Filed: Dec. 4, 2023

(51) Int. Cl. H01L 27/092; H01L 29/06; H01L 29/423; H01L 29/775; H01L 29/786

(52) U.S. Cl. CPC H10D 84/85; H10D 30/43; H10D 30/6735; H10D 30/6757; H10D 62/121

(57) ABSTRACT

A semiconductor structure includes a first nanosheet field-effect transistor device having a plurality of first nanosheet channel layers and a first interfacial layer surrounding each of the plurality of first nanosheet channel layers, the first interfacial layer having a first thickness, and a second nanosheet field-effect transistor device vertically stacked above the first field-effect transistor nanosheet device, the second field-effect transistor nanosheet device having a plurality of second nanosheet channel layers and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

### BACKGROUND

Stacking devices such as field-effect transistors (FETs) in the vertical direction gives an additional dimension for complementary metal-oxide-semiconductor (CMOS) area scaling. A FET is a transistor having a source, a gate, and a drain, the operation of which depends on the flow of carriers (electrons or holes) along a channel that runs between the source and drain. Current through the channel between the source and drain may be controlled by a transverse electric field under the gate. FETs are widely used for switching, amplification, filtering, and other tasks.

### SUMMARY

Illustrative embodiments of the present disclosure include techniques for use in semiconductor manufacture. In an illustrative embodiment, a semiconductor structure comprises a first nanosheet field-effect transistor device comprising a plurality of first nanosheet channel layers and a first interfacial layer surrounding each of the plurality of first nanosheet channel layers, the first interfacial layer having a first thickness. The semiconductor structure further comprises a second nanosheet field-effect transistor device vertically stacked above the first field-effect transistor nanosheet device, the second field-effect transistor nanosheet device comprising a plurality of second nanosheet channel layers and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

The semiconductor structure of the illustrative embodiment advantageously allows for forming an interfacial layer on each of the nanosheet channel layers of a first nanosheet field-effect transistor device and a second nanosheet field-effect transistor device in a stacked configuration where the interfacial layers of the second nanosheet field-effect transistor device have a thickness greater than a thickness of the interfacial layers of the first nanosheet field-effect transistor device thereby allowing for the formation of the same work function metal on the first nanosheet field-effect transistor device and the second nanosheet field-effect transistor device resulting in appropriate threshold voltages for each device (e.g., PFET and NFET devices) individually.

In one or more additional illustrative embodiments, as may be combined with the preceding paragraphs, the distance between each of the plurality of second nanosheet channel layers is from about 1 to about 3 nanometers less than the distance between each of the plurality of first nanosheet channel layers.

In one or more additional illustrative embodiments, as may be combined with the preceding paragraphs, the first interfacial layers and the second interfacial layers comprise the same interfacial material.

In one or more additional illustrative embodiments, as may be combined with the preceding paragraphs, the first interfacial layers have a thickness of about 0.1 to about 0.5 nm and the second interfacial layers have a thickness of about 0.5 to about 1.0 nm.

In one or more additional illustrative embodiments, as may be combined with the preceding paragraphs, the semiconductor structure further comprises a dielectric layer surrounding each of the first interfacial layers and the second interfacial layers.

In one or more additional illustrative embodiments, as may be combined with the preceding paragraphs, the dielectric layer comprises a high-k dielectric material with a k-value greater than 3.9.

In one or more additional illustrative embodiments, as may be combined with the preceding paragraphs, the semiconductor structure further comprises a work function metal disposed on the dielectric layer surrounding each of the first interfacial layers and the second interfacial layers.

In one or more additional illustrative embodiments, as may be combined with the preceding paragraphs, the work function metal is a p-type work function metal.

In one or more additional illustrative embodiments, as may be combined with the preceding paragraphs, the first nanosheet field-effect transistor device is of a first polarity and the second nanosheet field-effect transistor device is of a second polarity different than the first polarity.

In another illustrative embodiment, a semiconductor structure comprises an N-type nanosheet field-effect transistor device comprising a plurality of first nanosheet channel layers having a first length and a first interfacial layer surrounding each of the plurality of first nanosheet channel layers, the first interfacial layer having a first thickness. The semiconductor structure further comprises a P-type nanosheet field-effect transistor device vertically stacked above the N-type nanosheet field-effect transistor device, the P-type nanosheet field-effect transistor device comprising a plurality of second nanosheet channel layers having a second length and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

The semiconductor structure of the illustrative embodiment advantageously allows for forming an interfacial layer on each of the nanosheet channel layers of an N-type nanosheet field-effect transistor device and a P-type nanosheet field-effect transistor device in a stacked configuration where the interfacial layers of the P-type nanosheet field-effect transistor device have a thickness greater than a thickness of the interfacial layers of the N-type nanosheet field-effect transistor device thereby allowing for the formation of the same work function metal on the N-type nanosheet field-effect transistor device and the P-type nanosheet field-effect transistor device resulting in appropriate threshold voltages for each device (e.g., PFET and NFET devices) individually.

In one or more additional illustrative embodiments, as may be combined with the preceding paragraphs, the distance between each of the plurality of second nanosheet channel layers is from about 1 to about 3 nanometers less than the distance between each of the plurality of first nanosheet channel layers.

In one or more additional illustrative embodiments, as may be combined with the preceding paragraphs, the first interfacial layers and the second interfacial layers comprise the same interfacial material.

In one or more additional illustrative embodiments, as may be combined with the preceding paragraphs, the semiconductor structure further comprises a dielectric layer surrounding each of the first interfacial layers and the second interfacial layers.

In one or more additional illustrative embodiments, as may be combined with the preceding paragraphs, the dielectric layer is a high-k dielectric material with a k-value greater than 3.9.

In one or more additional illustrative embodiments, as may be combined with the preceding paragraphs, the semiconductor structure further comprises a work function metal disposed on the dielectric layer surrounding each of the first interfacial layers and the second interfacial layers.

In one or more additional illustrative embodiments, as may be combined with the preceding paragraphs, the work function metal is a p-type work function metal.

Another exemplary embodiment comprises an integrated circuit comprising one or more semiconductor structures. At least one of the one or more semiconductor structures is a semiconductor structure according to one or more of the foregoing embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 is a cross-sectional view of a semiconductor structure during an intermediate step of a method of fabricating a nanosheet transistor structure, according to an illustrative embodiment.

FIG. 2 is a cross-sectional view of the semiconductor structure following removal of sacrificial layers and growing an interfacial layer on each of a plurality of nanosheet channel layers, a middle dielectric insulator layer and on a top surface of a substrate, according to an illustrative embodiment.

FIG. 3 is a cross-sectional view illustrating the semiconductor structure following deposition of a dielectric layer on the interfacial layer, according to an illustrative embodiment.

FIG. 4 is a cross-sectional view illustrating the semiconductor structure following deposition of a cap layer on the dielectric layer, according to an illustrative embodiment.

FIG. 5 is a cross-sectional view illustrating the semiconductor structure following deposition of a scavenging layer on the cap layer, according to an illustrative embodiment.

FIG. 6 is a cross-sectional view of the semiconductor structure following deposition of another cap layer on the exposed surfaces of the scavenging layer, deposition of an anneal capping layer on the other cap layer, followed by a spike anneal and laser spike anneal according to an illustrative embodiment.

FIG. 7 is a cross-sectional view illustrating the semiconductor structure following removal of the anneal capping layer and the other cap layer, according to an illustrative embodiment.

FIG. 8 is a cross-sectional view of the semiconductor structure following deposition of a work function metal on the dielectric layer, according to an illustrative embodiment.

FIG. 9 is a cross-sectional view illustrating the semiconductor structure following deposition of a gate fill metal on the work function metal, according to an illustrative embodiment.

### DETAILED DESCRIPTION

Illustrative embodiments of the invention may be described herein in the context of illustrative methods for forming interfacial layers on nanosheet channel layers of a first nanosheet field-effect transistor device and a second nanosheet field-effect transistor device in a stacked configuration where the interfacial layer of the second nanosheet field-effect transistor device has a thickness greater than a thickness of the interfacial layer of the first nanosheet field-effect transistor device thereby allowing for forming the same work function metal on each of the first nanosheet field-effect transistor device and the second nanosheet field-effect transistor device e resulting in appropriate threshold voltages for each device (e.g., PFET and NFET devices) individually, along with illustrative apparatus, structures and devices formed using such methods. However, it is to be understood that embodiments of the invention are not limited to the illustrative methods, apparatus, structures and devices but instead are more broadly applicable to other suitable methods, apparatus, structures and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

Present stacked FET architecture suffers from the issue that P-type FETs and N-type FETs are at the same physical location of the semiconductor device and are stacked vertically. Accordingly, masking strategies that may be applicable for structures with P-type FETs and N-type FETs at different area locations of the semiconductor device, cannot be used for stacked FETs. In addition, matched work function gate stacks are indispensable to achieve appropriate threshold voltages for P-type FETs and N-type FETs individually. Process scalability (e.g., gate length scaling) however poses stringent requirements on work function metal thickness, dielectric insulator thickness between both stacks and ODL/Wet barrier space. Several proposed strategies have been attempted to overcome these drawbacks including blanket deposition of the work function metal matched to the bottom FET and then recessing from the top FET and redepositing the work function metal matched to the top FET. However, atomic layer recess from the top FET while maintaining the integrity of the work function metal of the bottom FET is difficult and unreliable. Thus, there is no known reliable method/structure to achieve a matched work function metal for stacked FET devices. Accordingly, non-limiting illustrative embodiments described herein overcome the drawbacks discussed above.

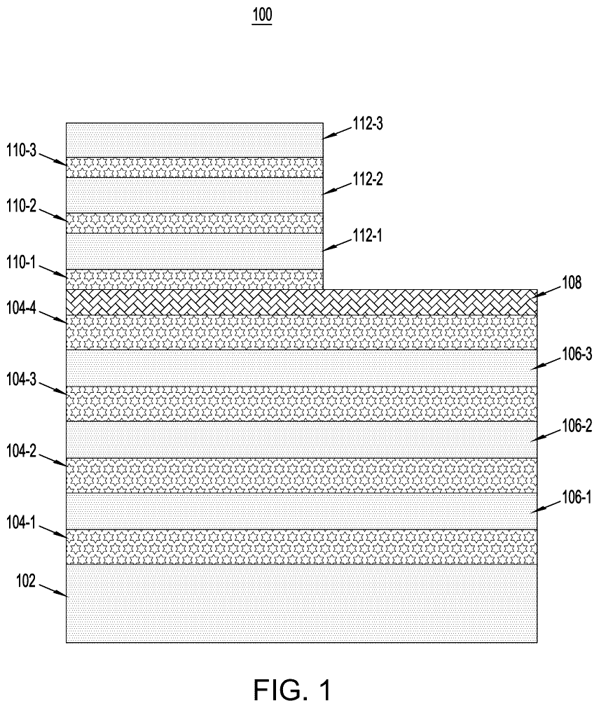

Referring now to the drawings in which like numerals represent the same of similar elements, FIGS. 1-9 illustrate various processes for fabricating semiconductor structures having a first nanosheet field-effect transistor device and a second nanosheet field-effect transistor device in a stacked configuration where the interfacial layer on nanosheet channel layers of the second nanosheet field-effect transistor device has a thickness greater than the thickness of the interfacial layer on nanosheet channel layers of the first nanosheet field-effect transistor device. Note that the same reference numeral (100) is used to denote the semiconductor structure through the various intermediate fabrication stages illustrated in FIGS. 1-9. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-9 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIG. 1, a semiconductor structure 100 is shown during an intermediate step of a method of fabricating a nanosheet transistor structure according to an embodiment of the invention. The semiconductor structure 100 includes a substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, the substrate 102 is silicon.

A first nanosheet stack (also referred to as first nanosheet device) is formed over the substrate 102, where the nanosheets include sacrificial layers 104-1, 104-2, 104-3 and 104-4 (collectively, the sacrificial layers 104), and nanosheet channel layers 106-1, 106-2 and 106-3 (collectively, the nanosheet channel layers 106).

The sacrificial layers 104 are illustratively formed of a sacrificial material, such that they may be etched or otherwise removed selectively. In some embodiments, the sacrificial layers 104 are formed of SiGe. For example, the sacrificial layers 104 may have a relatively higher percentage of Ge (e.g., 55% Ge) or a relatively lower percentage of Ge (e.g., 25% Ge).

The nanosheet channel layers 106 may be formed of Si or another suitable material (e.g., a material similar to that used for the substrate 102).

In some embodiments, the sacrificial layers 104 and the nanosheet channel layers 106 have a uniform length. For example, the sacrificial layers 104 and the nanosheet channel layers 106 can have a length ranging from about 20 to about 100 nanometers (nm).

In some embodiments, the sacrificial layers 104 have a first thickness and the nanosheet channel layers 106 have a second thickness. In some embodiments, the first thickness is the same as the second thickness. For example, the sacrificial layers 104 and the nanosheet channel layers 106 can have a thickness ranging from about 5 to about 15 nm.

Although four layers of the sacrificial layers 104 and three layers of the nanosheet channel layers 106 are shown, the number of the sacrificial layers 104 and the nanosheet channel layers 106 should not be considered limiting and any number of layers are contemplated.

In some embodiments, the first nanosheet stack will be an n-type nanosheet device (i.e., and NFET).

A second nanosheet stack (also referred to as second nanosheet device) is formed over the substrate 102, where the nanosheets include sacrificial layers 110-1, 110-2 and 110-3 (collectively, the sacrificial layers 110), and nanosheet channel layers 112-1, 112-2 and 112-3 (collectively, the nanosheet channel layers 112).

The sacrificial layers 110 are illustratively formed of a sacrificial material, such that they may be etched or otherwise removed selectively. In some embodiments, the sacrificial layers 110 are formed of SiGe. For example, the sacrificial layers 110 may have a relatively higher percentage of Ge (e.g., 55% Ge) or a relatively lower percentage of Ge (e.g., 25% Ge).

The nanosheet channel layers 112 may be formed of Si or another suitable material (e.g., a material similar to that used for the substrate 102).

In some embodiments, the sacrificial layers 110 and the nanosheet channel layers 112 have a uniform length. For example, the sacrificial layers 110 and the nanosheet channel layers 112 can have a length ranging from about 20 to about 100 nm. Although the sacrificial layers 110 and the nanosheet channel layers 112 are shown having a length less than the length of the sacrificial layers 104 and the nanosheet channel layers 106, this is merely illustrative and it is also contemplated that the sacrificial layers 110 and the nanosheet channel layers 112 can have the same length as the sacrificial layers 104 and the nanosheet channel layers 106.

In some embodiments, the sacrificial layers 110 have a first thickness and the nanosheet channel layers 112 have a second thickness. In some embodiments, the first thickness is less than the second thickness. For example, the sacrificial layers 110 can have a thickness ranging from about 5 to about 15 nm and the nanosheet channel layers 106 can have a thickness ranging from about 5 to about 15 nm.

In some embodiments, the sacrificial layers 110 can have a thickness less than the thickness of the sacrificial layers 104. In some embodiments, the sacrificial layers 110 can have a thickness less than the thickness of the sacrificial layers 104 and the nanosheet channel layers 112 can have a thickness that is the same as the thickness of the nanosheet channel layers 106. In some embodiments, the second stacked device having the nanosheet channel layers 112 can have a smaller Tsus (i.e., the distance between each of the respective nanosheet channel layers 112 of the plurality of nanosheet channel layers 112) than the Tsus of the first nanosheet device having the nanosheet channel layers 106 (i.e., the distance between each of the respective nanosheet channel layers 106 of the plurality of nanosheet channel layers 106). In some embodiments, by forming the sacrificial layers 110 with a thickness less than the thickness of the sacrificial layers 104, the second stacked device having the nanosheet channel layers 112 can have a smaller Tsus (i.e., the distance between each of the respective nanosheet channel layers 112 of the plurality of nanosheet channel layers 112) than the Tsus of the first nanosheet device having the nanosheet channel layers 106 (i.e., the distance between each of the respective nanosheet channel layers 106 of the plurality of nanosheet channel layers 106). In some embodiments, the second nanosheet device can have a Tsus of about 1 to about 3 nm less than the Tsus of the first nanosheet device (i.e., where the distance between each of the respective nanosheet channel layers 112 of the plurality of nanosheet channel layers 112 is from about 1 to about 3 nm less than the distance between each of the respective nanosheet channel layers 106 of the plurality of nanosheet channel layers 106). In some embodiments, the second nanosheet device can have a Tsus of about 1.5 to about 2.5 nm less than the Tsus of the first nanosheet device (i.e., where the distance between each of the respective nanosheet channel layers 112 of the plurality of nanosheet channel layers 112 is from about 1.5 to about 2.5 nm less than the distance between each of the respective nanosheet channel layers 106 of the plurality of nanosheet channel layers 106).

Although three layers of the sacrificial layers 110 and three layers of the nanosheet channel layers 112 are shown, the number of the sacrificial layers 110 and the nanosheet channel layers 112 should not be considered limiting and any number of layers are contemplated.

In some embodiments, the second nanosheet stack will be a p-type nanosheet device (i.e., a PFET).

The semiconductor structure 100 further includes a middle dielectric insulator (MDI) layer 108 separating the first nanosheet stack containing the sacrificial layers 104 and the nanosheet channel layers 106 from the second nanosheet stack containing the sacrificial layers 110 and the nanosheet channel layers 112. The MDI layer 108 may be formed of any suitable insulator or dielectric material, such as SiN, silicon boron carbide nitride (SiBCN), silicon oxycarbonitride (SiOCN), etc.

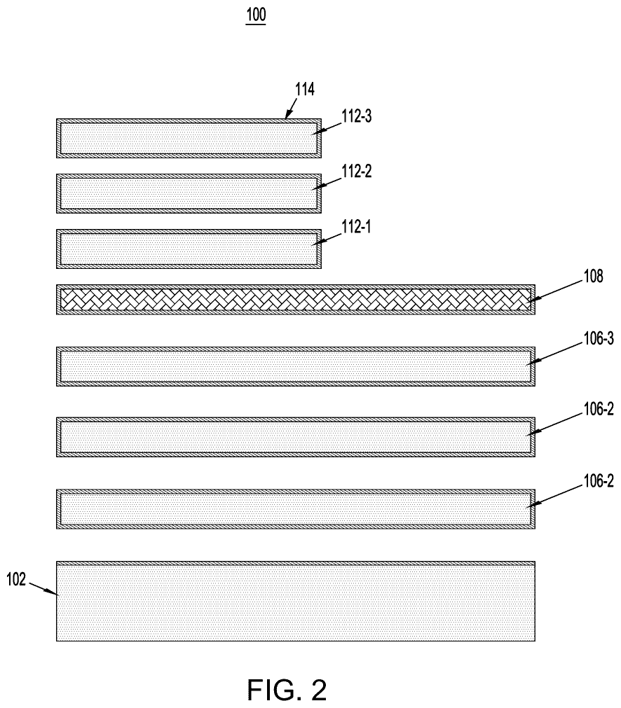

Referring now to FIG. 2, the semiconductor structure 100 is shown after removing the sacrificial layers 104 and 110, followed by growing an interfacial layer 114 on each of the nanosheet channel layers 106 and 112, the MDI layer 108 and on a top surface of the substrate 102 according to an embodiment of the invention. The sacrificial layers 104 and 110 are removed using a selective etching process such as a wet or dry etch that is selective to the sacrificial layers 104 and 110 relative to the nanosheet channel layers 106 and 112. In some embodiments, because the sacrificial layers 104 and 110 are formed from SiGe, they can be selectively etched with respect to the nanosheet channel layers 106 and 112 formed from Si using, for example, a vapor phase hydrogen chloride (HCL) gas isotropic etch process.

Next, the interfacial layer 114 is grown on each of the nanosheet channel layers 106 and 112, the MDI layer 108 and on the top surface of the substrate 102. In one embodiment, a suitable material for the interfacial layer 114 includes, for example, SiO₂ and SiON that surrounds each of the nanosheet channel layer 106 and each of the nanosheet channel layer 112.

In some embodiments, the interfacial layer 114 can be silicon oxide using, for example, a chemical oxidation process in an ozonated deionized water comprising ozone, and a suitable oxidation temperature, ozone concentration in the deionized water, and chemical oxidation process time to form interfacial silicon oxide layers. The interfacial layer 114 is formed by oxidizing the exposed silicon surfaces of the nanosheet channel layers 106 and 112 to form thin interfacial silicon oxide layers.

In some embodiments, the interfacial layer 114 can have a thickness ranging from about 0.1 to about 1 nm. In some embodiments, the interfacial layer 114 can have a thickness ranging from about 0.1 to about 0.5 nm. In some embodiments, the interfacial layer 114 can have a thickness ranging from about 0.5 to about 1.0 nm.

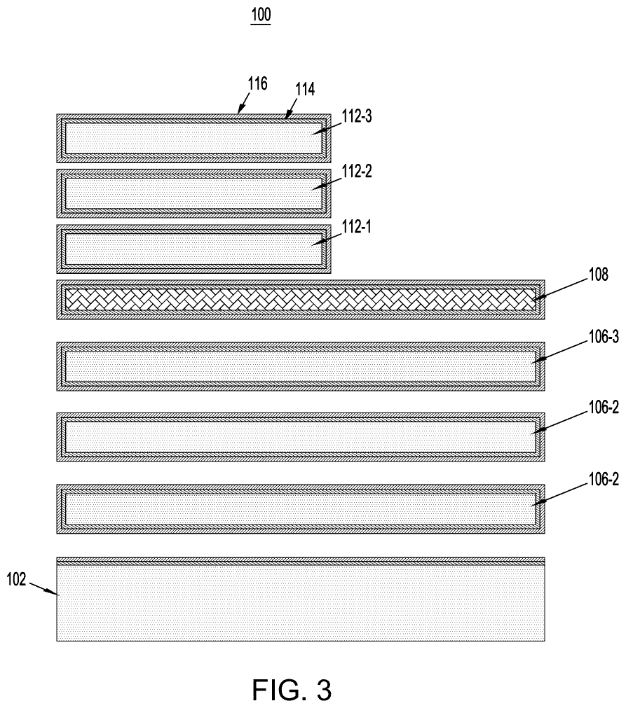

Referring now to FIG. 3, the semiconductor structure 100 is shown after depositing a dielectric layer 116 on the interfacial layer 114 according to an embodiment of the invention. The dielectric layer 116 is deposited using any conventional deposition technique such as ALD, CVD, PECVD, CVD, PVD, evaporation, chemical solution deposition, or other like processes. A suitable dielectric material for the dielectric layer 116 includes, for example, a high-k gate dielectric material that surrounds the interfacial layer 114. Suitable high-k materials include, for example, metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. In some embodiment, a suitable dielectric material for dielectric layer 116 includes, for example, a high-k gate dielectric material with a k-value greater than 3.9.

In some embodiments, the dielectric layer 116 can have a thickness ranging from about 1.0 to about 2.0 nm. In some embodiments, the dielectric layer 116 can have a thickness ranging from about 1.5 to about 1.8 nm.

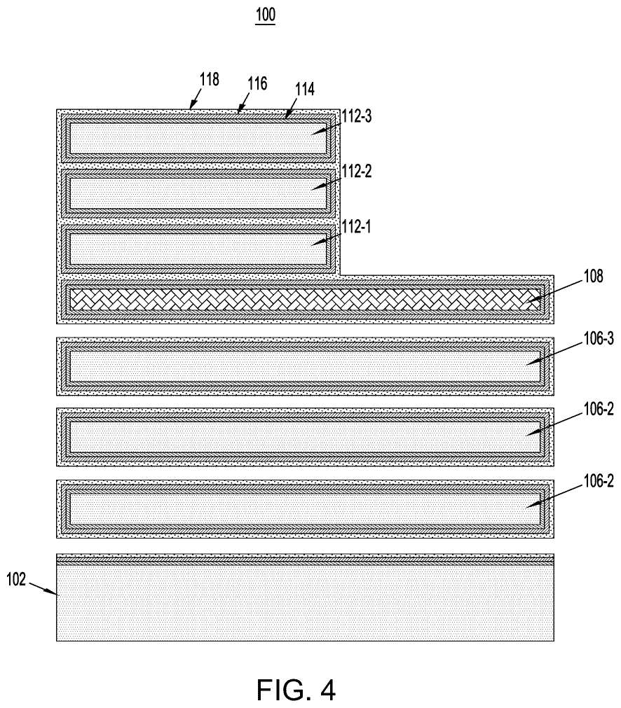

Referring now to FIG. 4, the semiconductor structure 100 is shown after depositing a cap layer 118 on the dielectric layer 116 according to an embodiment of the invention. The cap layer 118 can be deposited using any conventional deposition technique such as ALD, CVD, PVD, etc. Suitable material for the cap layer 118 includes, for example, a nitride material such as TiN, TaN and the like. The cap layer 118 formed on the dielectric layer 116 between the nanosheet channel layers 112 in the second nanosheet device results in pinching off the second nanosheet device.

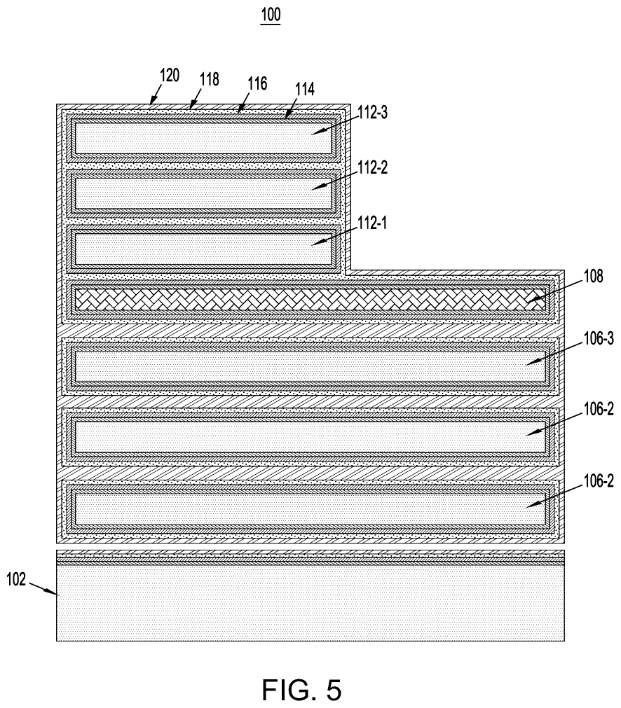

Referring now to FIG. 5, the semiconductor structure is shown after depositing a scavenging layer 120 on the cap layer 118 according to an embodiment of the invention. The scavenging layer 120 is deposited using any conventional deposition technique such as ALD, CVD, PVD, etc. Suitable material for the scavenging layer 120 includes, for example, titanium aluminum carbide (TiAlC), titanium aluminum (TiAl), tantalum aluminum carbide (TaAlC), Tantalum aluminum (TaAl), aluminum carbide (AlC), and other aluminum containing alloys. The scavenging layer 120 deposited on the cap layer 118 between the nanosheet channel layers 106 in the first nanosheet device results in pinching off the first nanosheet device.

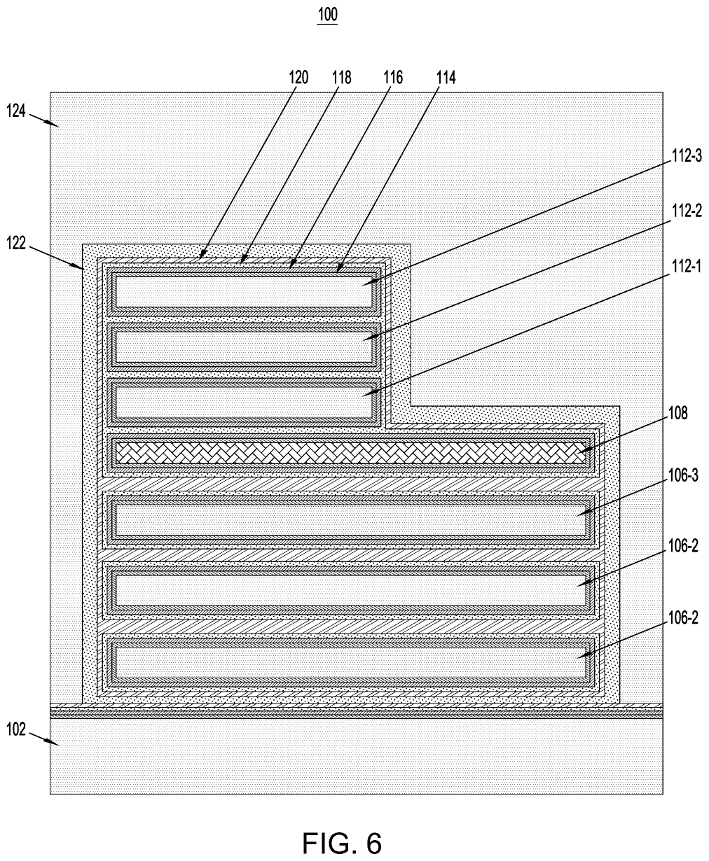

Referring now to FIG. 6, the semiconductor structure 100 is shown after depositing a cap layer 122 on the exposed surfaces of the scavenging layer 120, depositing an anneal capping layer 124 on the cap layer 122, followed by a spike anneal and laser spike anneal according to an embodiment of the invention. The cap layer 122 is deposited using any conventional deposition technique such as ALD, CVD, PVD, etc. Suitable material for the cap layer 122 includes, for example, a nitride material such as TiN, TaN and the like. In some embodiments, the cap layer 122 can have a thickness ranging from about 1.0 to about 3.0 nm.

Next, the anneal capping layer 124 is deposited on the cap layer 122 using any conventional deposition technique such as ALD, CVD, PVD, etc. Suitable material for the anneal capping layer 124 includes, for example, amorphous silicon, poly crystalline silicon, and the like. In some embodiments, the anneal capping layer 124 can have a thickness ranging from about 10 to about 20 nm.

Following the deposition of the anneal capping layer 124, the spike anneal is carried on the semiconductor structure 100, followed by the laser spike anneal. In some embodiments the spike anneal is carried out at a temperature of about 900° C. to about 1000° C. and for a time period ranging from about 0.001 to about 1 second. In some embodiments the laser spike anneal is carried out at a temperature of about 1100° C. to about 1300° C. and for a time period ranging from about 0.000001 to about 0.001 second.

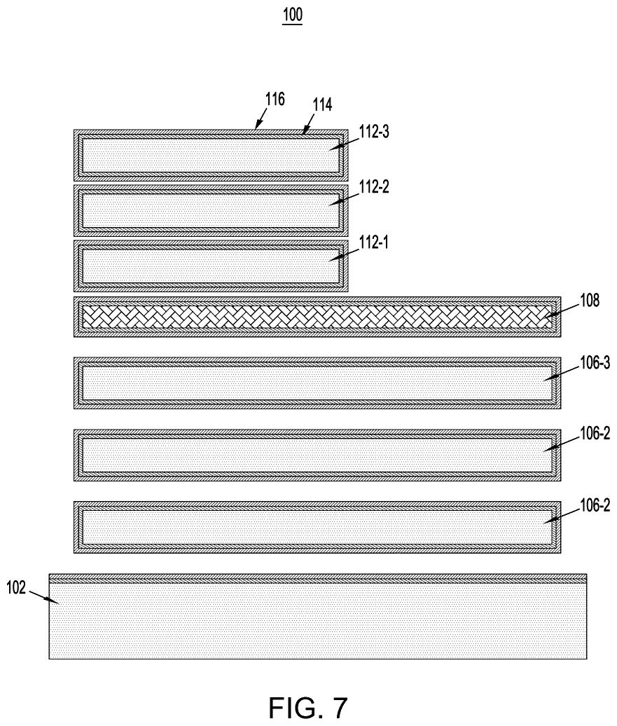

Referring now to FIG. 7, the semiconductor structure 100 is shown after removing the anneal capping layer 124 and the cap layer 122 according to an embodiment of the invention. The anneal capping layer 124 is first removed using any suitable etching process such as RIE. The cap layer 122 is then removed using any suitable etching process such as an anisotropic etch. The scavenging layer 120 is then removed using any suitable etching process such as an anisotropic etch. Following removal of these layers, the interfacial layer 114 on the nanosheet channel layers 106 of the first nanosheet device will have a thickness less than the original thickness. In other words, the interfacial layer 114 on the nanosheet channel layers 106 of the first nanosheet device will have a thickness less than the thickness of the interfacial layer 114 on the nanosheet channel layers 112 of the second nanosheet device. In some embodiments, the interfacial layer 114 on the nanosheet channel layers 106 of the first nanosheet device can have a thickness ranging from about 0.1 to about 0.5 nm. In some embodiment, the interfacial layer 114 on the nanosheet channel layers 112 of the second nanosheet device can have a thickness of about 0.5 to about 1 nm.

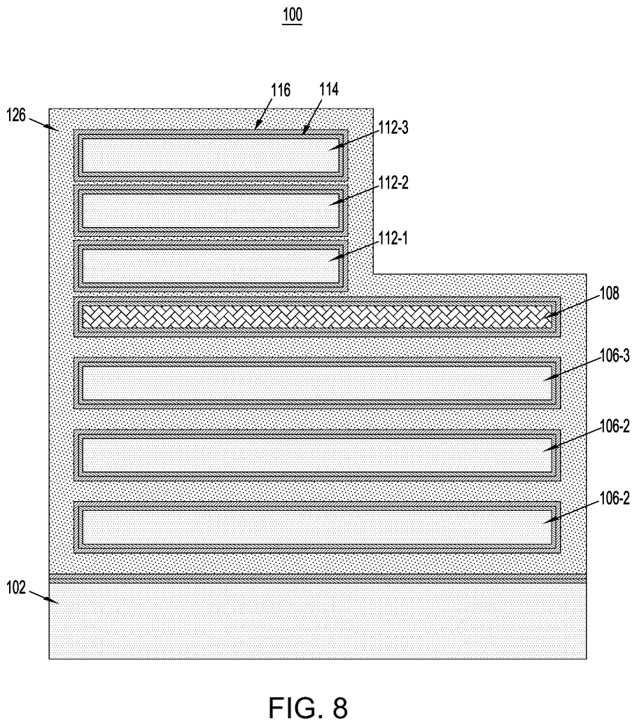

Referring now to FIG. 8, the semiconductor structure 100 is shown after depositing a work function metal 126 on the dielectric layer 116 for both the first nanosheet device and the second nanosheet device according to an embodiment of the invention. The work function metal 126 may be deposited by a suitable deposition process such as ALD, CVD, PECVD, PVD, plating, and thermal or e-beam evaporation. In some embodiments, the first nanosheet device is of a first polarity and the second nanosheet device is of a second polarity different than the first polarity. In some embodiments, the first nanosheet device is an N-type nanosheet field-effect transistor device and the second nanosheet device is a P-type nanosheet field-effect transistor device. In embodiments including nFET and pFET regions, the work function metal is deposited on both of the regions using the same work function metal. In some embodiments, the work function metal employed is a p-type work function metal including, by way of example, TiN, TaN or a tungsten (W) layer. As discussed above, the interfacial layer 114 on the nanosheet channel layers 106 of the first nanosheet device will have a thickness less than the thickness of the interfacial layer 114 on the nanosheet channel layers 112 of the second nanosheet device thereby allowing for the formation of the same work function metal for the first nanosheet device and the second nanosheet device resulting in appropriate threshold voltages for each device (e.g., PFET and NFET devices).

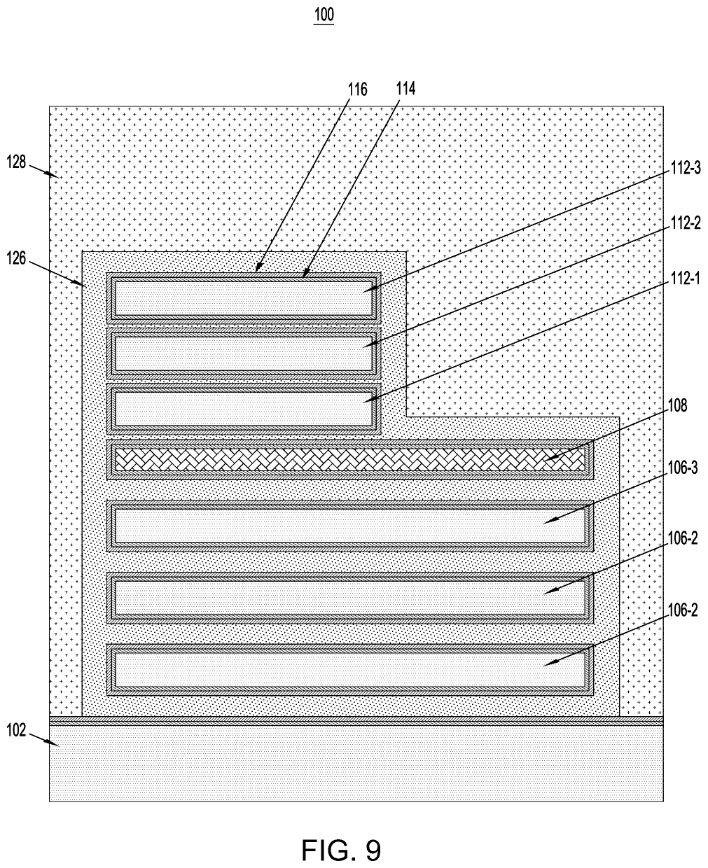

Referring now to FIG. 9, the semiconductor structure 100 is shown after depositing a gate fill metal 128 on the work function metal 126 to fill the remaining space of the semiconductor structure 100 according to an embodiment of the invention. The gate fill metal 128 may include a metal gate composed of a high conductive material. Suitable high conductive metals include, for example, conductive material such as, for example, tungsten (W), aluminum (Al), copper (Cu), cobalt (Co), ruthenium (Ru), molybdenum (Mo), or any other suitable conductive material. In various embodiments, the high conductive metal can be deposited by ALD, CVD, PVD, and/or plating. The high conductive metal can be planarized using, for example, a planarizing process such as CMP. Other planarization processes can include grinding and polishing.

According to an aspect of the invention, a semiconductor structure comprises a first nanosheet field-effect transistor device comprising a plurality of first nanosheet channel layers and a first interfacial layer surrounding each of the plurality of first nanosheet channel layers, the first interfacial layer having a first thickness. The semiconductor structure further comprises a second nanosheet field-effect transistor device vertically stacked above the first field-effect transistor nanosheet device, the second field-effect transistor nanosheet device comprising a plurality of second nanosheet channel layers and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

In embodiments, the distance between each of the plurality of second nanosheet channel layers is from about 1 to about 3 nanometers less than the distance between each of the plurality of first nanosheet channel layers.

In embodiments, the first interfacial layers and the second interfacial layers comprise the same interfacial material.

In embodiments, the first interfacial layers have a thickness of about 0.1 to about 0.5 nm and the second interfacial layers have a thickness of about 0.5 to about 1.0 nm.

In embodiments, the semiconductor structure further comprises a dielectric layer surrounding each of the first interfacial layers and the second interfacial layers.

In embodiments, the dielectric layer comprises a high-k dielectric material with a k-value greater than 3.9.

In embodiments, the semiconductor structure further comprises a work function metal disposed on the dielectric layer surrounding each of the first interfacial layers and the second interfacial layers.

In embodiments, the work function metal is a p-type work function metal.

In embodiments, the first nanosheet field-effect transistor device is of a first polarity and the second nanosheet field-effect transistor device is of a second polarity different than the first polarity.

According to an aspect of the invention, a semiconductor structure comprises an N-type nanosheet field-effect transistor device comprising a plurality of first nanosheet channel layers having a first length and a first interfacial layer surrounding each of the plurality of first nanosheet channel layers, the first interfacial layer having a first thickness. The semiconductor structure further comprises a P-type nanosheet field-effect transistor device vertically stacked above the N-type nanosheet field-effect transistor device, the P-type nanosheet field-effect transistor device comprising a plurality of second nanosheet channel layers having a second length and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

In embodiments, the distance between each of the plurality of second nanosheet channel layers is from about 1 to about 3 nanometers less than the distance between each of the plurality of first nanosheet channel layers.

In embodiments, the first interfacial layers and the second interfacial layers comprise the same interfacial material.

In embodiments, the semiconductor structure further comprises a dielectric layer surrounding each of the first interfacial layers and the second interfacial layers.

In embodiments, the dielectric layer is a high-k dielectric material with a k-value greater than 3.9.

In embodiments, the semiconductor structure further comprises a work function metal disposed on the dielectric layer surrounding each of the first interfacial layers and the second interfacial layers.

According to an aspect of the invention, an integrated circuit comprises one or more semiconductor structures, wherein at least one of the one or more semiconductor structures comprises a first nanosheet field-effect transistor device comprising a plurality of first nanosheet channel layers and a first interfacial layer surrounding each of the plurality of first nanosheet channel layers, the first interfacial layer having a first thickness, and a second nanosheet field-effect transistor device vertically stacked above the first field-effect transistor nanosheet device, the second field-effect transistor nanosheet device comprising a plurality of second nanosheet channel layers and a second interfacial layer surrounding each of the plurality of second nanosheet channel layers, the second interfacial layer having a second thickness greater than the first thickness. A distance between each of the plurality of second nanosheet channel layers is less than a distance between each of the plurality of first nanosheet channel layers.

In embodiments, the first nanosheet field-effect transistor device is an N-type nanosheet field-effect transistor device and the second nanosheet field-effect transistor device is a P-type nanosheet field-effect transistor device.

In embodiments, the at least one of the one or more semiconductor structures further comprises a dielectric layer surrounding each of the first interfacial layers and the second interfacial layers, and a p-type work function metal disposed on the dielectric layer.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first nanosheet field-effect transistor device comprising a plurality of first nanosheet channel layers and a first interfacial layer surrounding each of the plurality of first nanosheet channel layers, the first interfacial layer having a first thickness; and
a second nanosheet field-effect transistor device vertically stacked above the first field-effect transistor nanosheet device, the second field-effect transistor nanosheet device comprising a plurality of second nanosheet channel layers and a second interfacial layer surrounding each of the plurality of second nanosheet channel layers, the second interfacial layer having a second thickness greater than the first thickness;
wherein a distance between each of the plurality of second nanosheet channel layers is less than a distance between each of the plurality of first nanosheet channel layers.

2. The semiconductor structure according to claim 1, wherein the distance between each of the plurality of second nanosheet channel layers is from about 1 to about 3 nanometers (nm) less than the distance between each of the plurality of first nanosheet channel layers.

3. The semiconductor structure according to claim 1, wherein the first interfacial layers and the second interfacial layers comprise the same interfacial material.

4. The semiconductor structure according to claim 1, wherein the first interfacial layers have a thickness of about 0.1 to about 0.5 nm and the second interfacial layers have a thickness of about 0.5 to about 1.0 nm.

5. The semiconductor structure according to claim 1, further comprising a dielectric layer surrounding each of the first interfacial layers and the second interfacial layers.

6. The semiconductor structure according to claim 5, wherein the dielectric layer comprises a high-k dielectric material with a k-value greater than 3.9.

7. The semiconductor structure according to claim 5, further comprising a work function metal disposed on the dielectric layer surrounding each of the first interfacial layers and the second interfacial layers.

8. The semiconductor structure according to claim 7, wherein the work function metal is a p-type work function metal.

9. The semiconductor structure according to claim 7, further comprising a gate fill metal disposed over the work function metal.

10. The semiconductor structure according to claim 1, wherein the first nanosheet field-effect transistor device is of a first polarity and the second nanosheet field-effect transistor device is of a second polarity different than the first polarity.

11. A semiconductor structure, comprising:
an N-type nanosheet field-effect transistor device comprising a plurality of first nanosheet channel layers having a first length and a first interfacial layer surrounding each of the plurality of first nanosheet channel layers, the first interfacial layer having a first thickness; and
a P-type nanosheet field-effect transistor device vertically stacked above the N-type nanosheet field-effect transistor device, the P-type nanosheet field-effect transistor device comprising a plurality of second nanosheet channel layers having a second length and a second interfacial layer surrounding each of the plurality of second nanosheet channel layers, the second interfacial layer having a second thickness greater than the first thickness;
wherein a distance between each of the plurality of second nanosheet channel layers is less than a distance between each of the plurality of first nanosheet channel layers.

12. The semiconductor structure according to claim 11, wherein the distance between each of the plurality of second nanosheet channel layers is from about 1 to about 3 nanometers less than the distance between each of the plurality of first nanosheet channel layers.

13. The semiconductor structure according to claim 11, wherein the first interfacial layers and the second interfacial layers comprise the same interfacial material.

14. The semiconductor structure according to claim 11, further comprising a dielectric layer surrounding each of the first interfacial layers and the second interfacial layers.

15. The semiconductor structure according to claim 14, wherein the dielectric layer is a high-k dielectric material with a k-value greater than 3.9.

16. The semiconductor structure according to claim 14, further comprising a work function metal disposed on the dielectric layer surrounding each of the first interfacial layers and the second interfacial layers.

17. The semiconductor structure according to claim 16, wherein the work function metal is a p-type work function metal.

18. An integrated circuit, comprising:
one or more semiconductor structures, wherein at least one of the one or more semiconductor structures comprises:
a first nanosheet field-effect transistor device comprising a plurality of first nanosheet channel layers and a first interfacial layer surrounding each of the plurality of first nanosheet channel layers, the first interfacial layer having a first thickness; and
a second nanosheet field-effect transistor device vertically stacked above the first field-effect transistor nanosheet device, the second field-effect transistor nanosheet device comprising a plurality of second nanosheet channel layers and a second interfacial layer surrounding each of the plurality of second nanosheet channel layers, the second interfacial layer having a second thickness greater than the first thickness;
wherein a distance between each of the plurality of second nanosheet channel layers is less than a distance between each of the plurality of first nanosheet channel layers.

19. The integrated circuit according to claim 18, wherein the first nanosheet field-effect transistor device is an N-type nanosheet field-effect transistor device and the second nanosheet field-effect transistor device is a P-type nanosheet field-effect transistor device.

20. The integrated circuit according to claim 19, wherein the at least one of the one or more semiconductor structures further comprises a dielectric layer surrounding each of the first interfacial layers and the second interfacial layers; and a p-type work function metal disposed on the dielectric layer.
